(19) United States
(12) Patent Application Publication
(10) Pub. No.: US 2025/0192081 A1
(43) Pub. Date: Jun. 12, 2025

(54) WIRE BONDING STRUCTURE AND MANUFACTURING METHOD THEREOF

(71) Applicant: Realtek Semiconductor Corporation, Hsinchu (TW)

(72) Inventor: Wen Cheng YANG, Hsinchu (TW)

(21) Appl. No.: 18/830,554

(22) Filed: Sep. 10, 2024

(30) Foreign Application Priority Data
Dec. 8, 2023 (TW) 112147993

(51) Int. Cl. H01L 23/00

(52) U.S. Cl. CPC H01L 24/05; H01L 24/03; H01L 2224/0345; H01L 2224/03452; H01L 2224/03622; H01L 2224/04042; H01L 2224/05011; H01L 2224/05017; H01L 2224/05188; H01L 2224/05582; H01L 2224/05624

(57) ABSTRACT

A wire bonding structure and a manufacturing method thereof are provided. The wire bonding structure is suitable for chip packaging devices. The wire bonding structure includes a wire bonding pad layer, a metal layer and a buffer layer. The metal layer contacts and is underneath the wire bonding pad layer. The buffer layer contacts and is underneath the metal layer. The buffer layer has plural through holes spaced apart from each other. The through holes penetrate the buffer layer from top to bottom and correspondingly define plural low dielectric constant material blocks and plural air gaps that are laterally interleaved with each other in the cross-sectional direction.

### RELATED APPLICATIONS

This application claims priority to Taiwan Application Serial Number 112147993, filed Dec. 8, 2023, the disclosures of which are incorporated herein by reference in their entireties.

### BACKGROUND

### Field of Invention

The present invention relates to a wire bonding structure. More particularly, the present invention relates to a wire bonding structure and a manufacturing method thereof.

### Description of Related Art

In the field of chip packaging, a chip packaging structure and an electronic component can be electrically connected through a wire bonding technology. That is, a welding wire is used to form a solder joint on the chip packaging structure and to form another solder joint on the electronic component, such that the chip packaging structure is electrically connected the electronic component. However, a longitudinal forward pressure generated during the wire bonding operation will be transmitted to the wire bonded chip through via(s) of the wire bonded chip, which may affect the electrical characteristic(s) of electronic component inside the wire bonded chip and reduce the production yield of the wire bonded chip. Therefore, it is an important research topic to reduce the impact of the longitudinal forward pressure applied on the electronic component inside the wire bonded chip during the wire bonding operation, thereby improving the production yield of wire bonded chip.

### SUMMARY

The present invention provides a wire bonding structure suitable for chip packaging devices includes a wire bonding pad layer, a metal layer and a buffer layer. The metal layer contacts and is underneath the wire bonding pad layer. The buffer layer contacts and is underneath the metal layer. The buffer layer has plural through holes spaced apart from each other. The through holes penetrate the buffer layer from top to bottom and correspondingly define plural low dielectric constant material blocks and plural air gaps in a cross-sectional direction of the wire bonding structure, and the low dielectric constant material blocks and the air gaps are laterally interleaved with each other.

The present invention further provides a manufacturing method of a wire bonding structure includes: performing a first deposition process to form a low dielectric constant material layer; utilizing a patterned mask to perform an etching process on the low dielectric constant material layer, thereby forming a plurality of through holes penetrating the low dielectric constant material layer from top to bottom, in which the through holes define a plurality of low dielectric constant material blocks and a plurality of air gaps in a cross-sectional direction of the wire bonding structure, and the low dielectric constant material blocks and the air gaps are laterally interleaved with each other, and the low dielectric constant material blocks and the air gaps form a buffer layer; and performing a second deposition process to sequentially form a metal layer and a wire bonding pad layer on the buffer layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a wire bonding structure according to some embodiments of the present invention.

FIG. 2 illustrates simulation results of the impact on the longitudinal forward pressure when changing some dimensional parameters of the wire bonding structure of the present invention.

FIG. 3 illustrates simulation results of the impact on the longitudinal forward pressure when changing some dimensional parameters of the wire bonding structure of the present invention.

FIG. 4 illustrates a flow chart of a manufacturing method of the wire bonding structure according to some embodiments of the present invention.

FIG. 5a to FIG. 5f illustrate cross-sectional views of various stages of manufacturing the wire bonding structure according to some embodiment of the present invention.

FIG. 6 illustrates a structural diagram of a wire bonding type chip according to some embodiments of the present invention.

### DETAILED DESCRIPTION

Specific embodiments of the present invention are further described in detail below with reference to the accompanying drawings, however, the embodiments described are not intended to limit the present invention and it is not intended for the description of operation to limit the order of implementation. The using of “first”, “second”, “third”, etc. in the specification should be understood for identify units or data described by the same terminology, but are not referred to particular order or sequence.

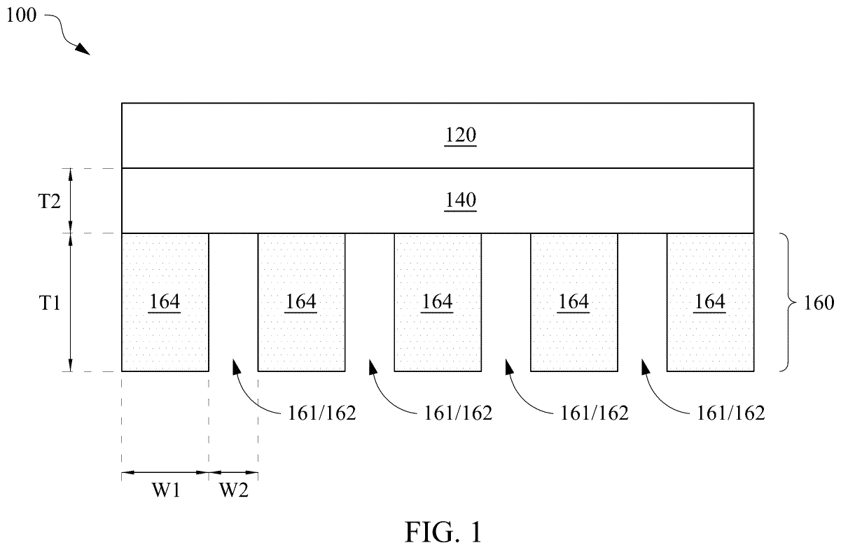

FIG. 1 illustrates a cross-sectional view of a wire bonding structure 100 according to some embodiments of the present invention. The wire bonding structure 100 is suitable for any chip packaging device using a wire bonding process, and the said chip packaging device is also known as a wire bonding type chip. Specifically, the present invention uses the wire bonding structure 100 to replace a wire bonding pad of the wire bonding type chip, and the wire bonding structure 100 can reduce a longitudinal forward pressure generated during the wire bonding operation to reduce the impact of the longitudinal forward pressure on the electronic component(s) inside the wire bonding type chip, thereby improving the production yield of the wire bonding type chip.

As shown in FIG. 1, the wire bonding structure 100 includes, from top to bottom, a wire bonding pad layer 120, a metal layer 140 and a buffer layer 160. The wire bonding pad layer 120 is a wire bonding pad of a wire bonding type chip, and is used for a wire bonding operation to be applied thereon. In other words, the present invention designs a special structure (i.e., the metal layer 140 and the buffer layer 160) under the wire bonding pad (i.e., the wire bonding pad layer 120) of the wire bonding type chip to reduce the longitudinal forward pressure generated during the wire bonding operation.

The metal layer 140 contacts and is underneath the wire bonding pad layer 120. Specifically, the wire bonding pad layer 120 and the metal layer 140 are made of the same material, in order to increase the adhesion between the wire bonding pad layer 120 and the metal layer 140. If the buffer layer 160 is added directly under the wire bonding pad layer 120, there may be a problem of poor adhesion between the wire bonding pad layer 120 and the buffer layer 160. In some embodiments of the present invention, the wire bonding pad layer 120 and the metal layer 140 are both made of aluminum, but the present invention is not limited thereto.

The buffer layer 160 contacts and is underneath the metal layer 140. The buffer layer 160 has plural through holes 161 spaced apart from each other. The through holes 161 penetrate the buffer layer 160 from top to bottom and correspondingly define plural low dielectric constant material blocks 164 and plural air gaps 162 in a cross-sectional direction of the wire bonding structure 100. The low dielectric constant material blocks 164 and plural air gaps 162 are laterally interleaved with each other. It should be noted that the number of the low dielectric constant material blocks 164 and the number of the air gaps 162 as shown in FIG. 1 are only an example, and the present invention is not limited thereto.

In some embodiments of the present invention, the low dielectric constant material blocks 164 are made of an undoped silicon glass (USG). In other embodiments of the present invention, the low dielectric constant material blocks 164 are made of oxide. In yet other embodiments of the present invention, the low dielectric constant material blocks 164 are made of low dielectric constant material (e.g., a material having a dielectric constant that is less than about 3) other than the undoped silicon glass and the oxide.

In some embodiments of the present invention, the low dielectric constant material blocks 164 have the same lateral width W1, and the air gaps 162 have the same lateral width W2. The aforementioned same width can enable the wire bonding structure 100 to evenly distribute the longitudinal forward pressure generated during the wire bonding operation.

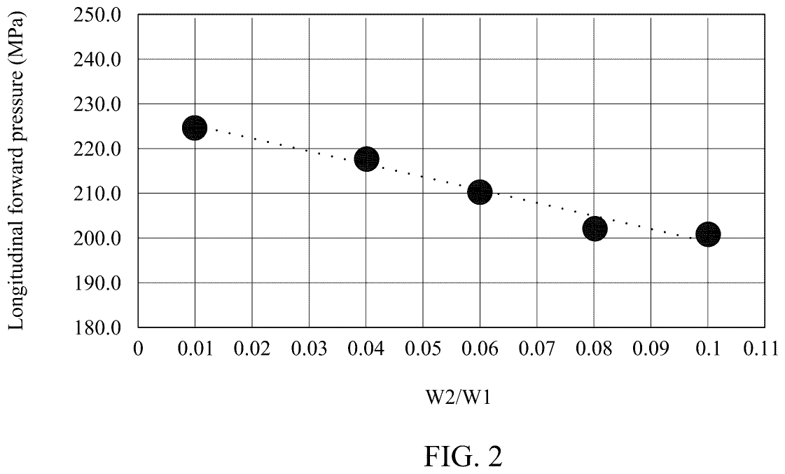

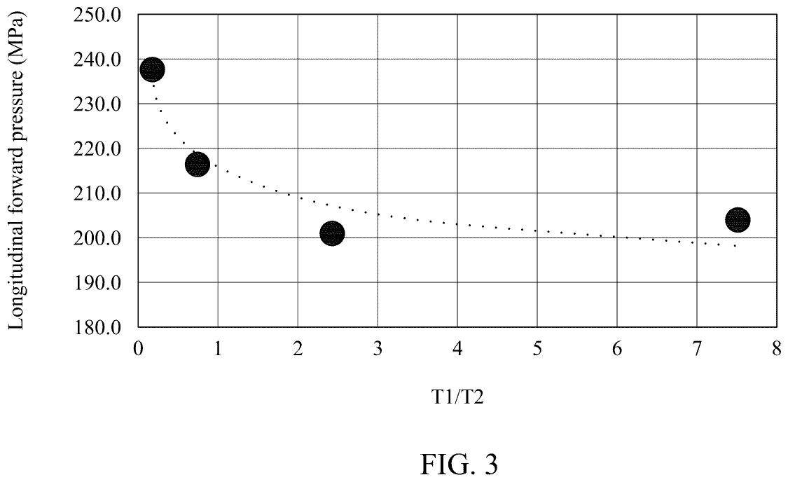

FIG. 2 and FIG. 3 illustrate simulation results of the impact on the longitudinal forward pressure when changing some dimensional parameters of the wire bonding structure 100 of the present invention. In FIG. 2, the X-axis corresponds to a ratio of the lateral width W2 (also called a second lateral width) of each of air gaps 162 to the lateral width W1 (also called a first lateral width) of each of the low dielectric constant material blocks 164, that is, W2/W1. In FIG. 3, the X-axis corresponds to a ratio of a thickness T1 (also called a first thickness) of the buffer layer 160 to a thickness T2 (also called a second the thickness) of the metal layer 140, that is, T1/T2. In FIG. 2 and FIG. 3, the Y-axis corresponds to the longitudinal forward pressure when performing a wire bonding operation on the wire bonding structure 100, and the said longitudinal forward pressure is transmitted from the wire bonding pad layer 120 through the metal layer 140 and the buffer layer 160 to reach a chip located below the buffer layer 160, and unit of the said longitudinal forward pressure is million pascals (MPa).

As shown in FIG. 2, when performing a wire bonding operation on the wire bonding structure 100, the longitudinal forward pressure (transmitted from the wire bonding pad layer 120 through the metal layer 140 and the buffer layer 160 to the chip located below the buffer layer 160) decreases with the increase of the ratio of W2/W1. The regression analysis is performed on values in FIG. 2 to obtain the following equation: Y=−287.33X+227.89, and a coefficient of determination (R²) of the above equation is 0.9719.

It is worth mentioning that, although the larger the W2/W1, the lower the longitudinal forward pressure of the wire bonding operation, however, the larger W2/W1 also means that the air gap 162 is wider than the low dielectric constant material block 164, which is not beneficial to the subsequent deposition process that the metal layer 140 is formed on the buffer layer 160. For example, if the air gap 162 is too wide, the air gap 162 will be filled by the metal layer 140. Therefore, according to the feasibility of the practical process, W2/W1 has an upper limit. In some embodiments of the present invention, a ratio of the lateral width W2 (also called the second lateral width) of each of the air gaps 162 to the lateral width W1 (also called the first lateral width) of each of the low dielectric constant material blocks 164 is between 0.01 and 0.1 (including the end points of the range).

As shown in FIG. 3, when performing a wire bonding operation on the wire bonding structure 100, the longitudinal forward pressure (transmitted from the wire bonding pad layer 120 through the metal layer 140 and the buffer layer 160 to the chip located below the buffer layer 160) decreases with the increase of the ratio of T1/T2. The regression analysis is performed on values in FIG. 3 to obtain the following equation: Y=−215.06X^{-0.041}, and a coefficient of determination (R²) of the above equation is 0.8701.

It is worth mentioning that, although the larger the T1/T2, the lower the longitudinal forward pressure of the wire bonding operation, however, as shown in FIG. 3, the longitudinal forward pressure tends to be fixed when the value of T1/T2 is about 1 to 3 (that is, the reduction of the longitudinal forward pressure approaches 0 when T1/T2 is larger than 3), and the larger the thickness T1 of the buffer layer 160, the thicker the chip packaging device will be. The thinner thickness T2 of the metal layer 140 is limited by the advancement of the process and the price and cost of the process, and thus the value of T1/T2 has an upper limit in practice. In some embodiments of the present invention, the ratio of the thickness T1 (also called the first thickness) of the buffer layer 160 to the thickness T2 (also called the second thickness) of the metal layer 140 is less than 8.

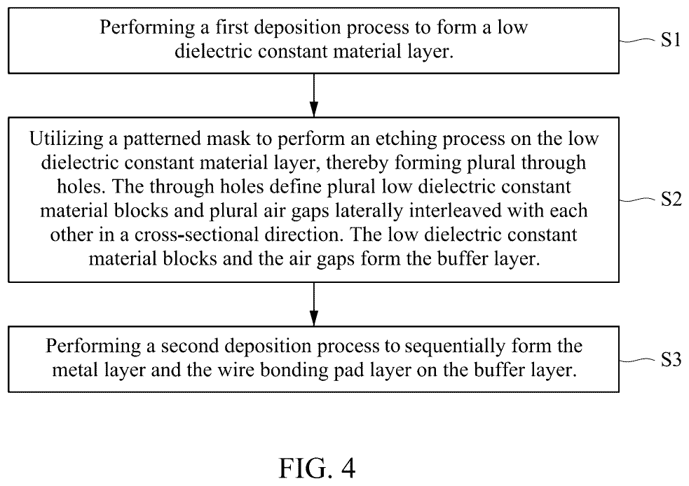

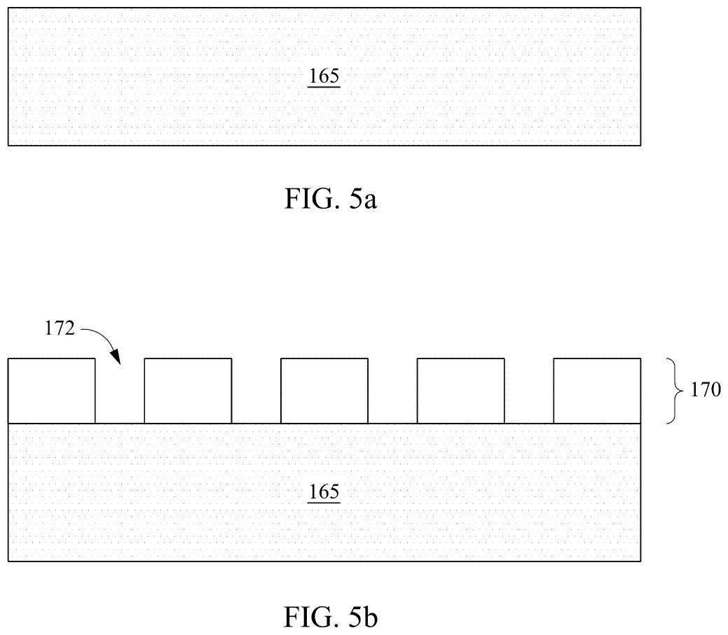

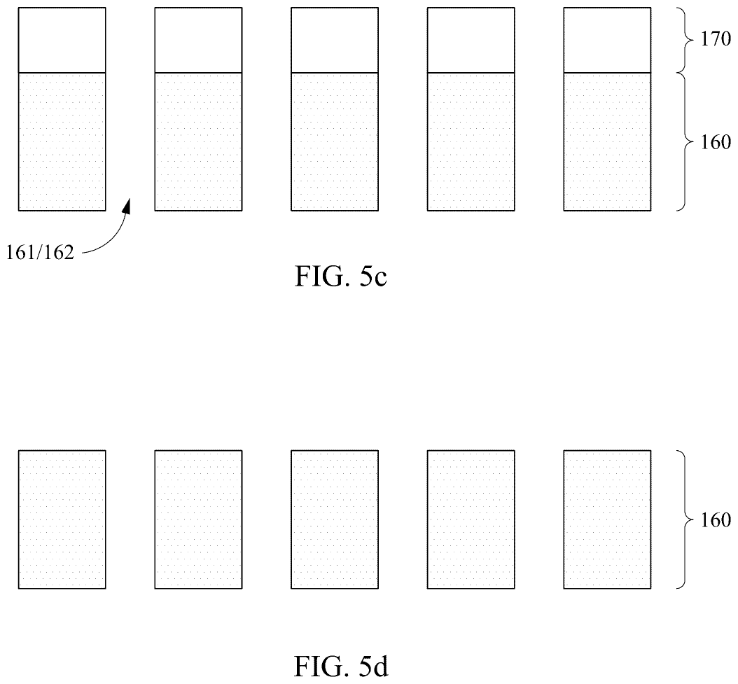

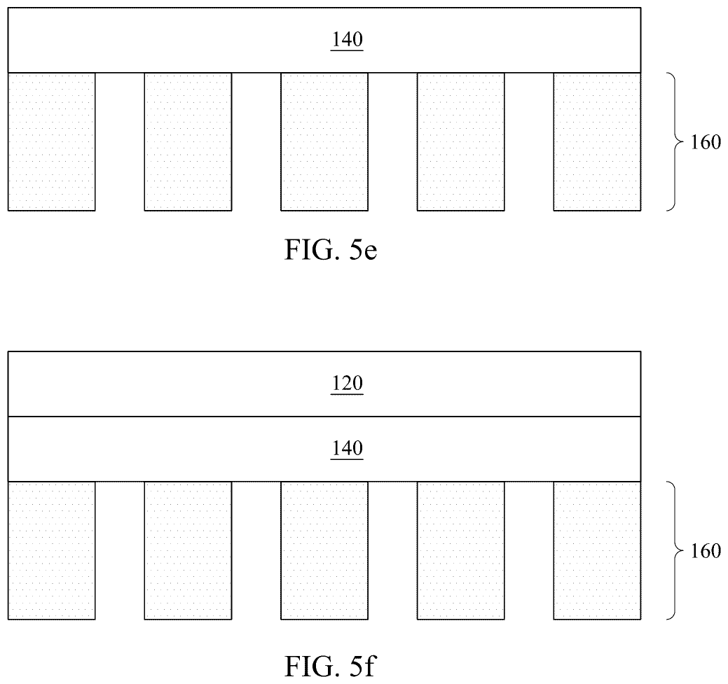

FIG. 4 illustrates a flow chart of a manufacturing method of the wire bonding structure 100 according to some embodiments of the present invention. The manufacturing method includes step S1, step S2, and step S3. FIG. 5a to FIG. 5f illustrate cross-sectional views of various stages of manufacturing the wire bonding structure 100 according to some embodiment of the present invention.

As shown in FIG. 4 and FIG. 5a, in step S1, a first deposition process is performed to form a low dielectric constant material layer 165. In some embodiments of the present invention, the first deposition process is a chemical vapor deposition (CVD) process. Specifically, the first deposition process is a CVD thin film deposition process. In some embodiments of the present invention, the low dielectric constant material layer 165 is made of an undoped silicon glass (USG), an oxide or another low dielectric constant material.

As shown in FIG. 4, FIG. 5b, FIG. 5c, and FIG. 5d, in step S2, a patterned mask 170 (also called a photoresist) is utilized to perform an etching process on the low dielectric constant material layer 165 (deposited in step S1), such that plural through holes 161 penetrating the low dielectric constant material layer 165 from top to bottom are formed in the low dielectric constant material layer 165. The through holes 161 define plural low dielectric constant material blocks 164 and plural air gaps 162 in a cross-sectional direction of the wire bonding structure, and the low dielectric constant material blocks 164 and the air gaps 162 are laterally interleaved with each other. The low dielectric constant material blocks 164 and the air gaps 162 form the buffer layer 160. In some embodiments of the present invention, the etching process in step S2 is a dry etching process (such as a plasma etching process) or a wet etching process (such as a chemical solution etching process).

As shown in FIG. 5b, the patterned mask 170 has plural openings 172, and the openings 172 are utilized to expose plural portions of the low dielectric constant material layer 165 and the aforementioned portions respectively correspond to the through holes 161.

As discussed above with respect to FIG. 2, during the wire bonding operation, the longitudinal forward pressure transmitted from the wire bonding pad layer 120 through the metal layer 140 and the buffer layer 160 to the chip located below the buffer layer 160 is associated with the ratio of the lateral width W2 of each of the air gaps 162 to the lateral width W1 of each of the low dielectric constant material blocks 164. Therefore, in some embodiments of the present invention, the patterned mask 170 may designed to adjust a width of each opening 172 of the patterned mask, thereby adjusting the ratio of the lateral width W2 of each of the air gaps 162 to the lateral width W1 of each of the low dielectric constant material blocks 164.

As shown in FIG. 4, FIG. 5e, and FIG. 5f, in step S3, a second deposition process is performed to sequentially form the metal layer 140 and the wire bonding pad layer 120 on the buffer layer 160. In some embodiments of the present invention, each of the wire bonding pad layer 120 and the metal layer 140 is made of aluminum.

As discussed above with respect to FIG. 3, during the wire bonding operation, the longitudinal forward pressure transmitted from the wire bonding pad layer 120 through the metal layer 140 and the buffer layer 160 to the chip located below the buffer layer 160 is associated with the ratio of the thickness T1 of the buffer layer 160 to the thickness T2 of the metal layer 140. Therefore, in some embodiments of the present invention, process parameters of the first deposition process and the second deposition process may adjusted to control the ratio of the thickness T1 of the buffer layer 160 to the thickness T2 of the metal layer 140. The above-mentioned process parameters include, for example, a deposition time, a gas flow rate, a liquid flow rate, a process pressure, etc.

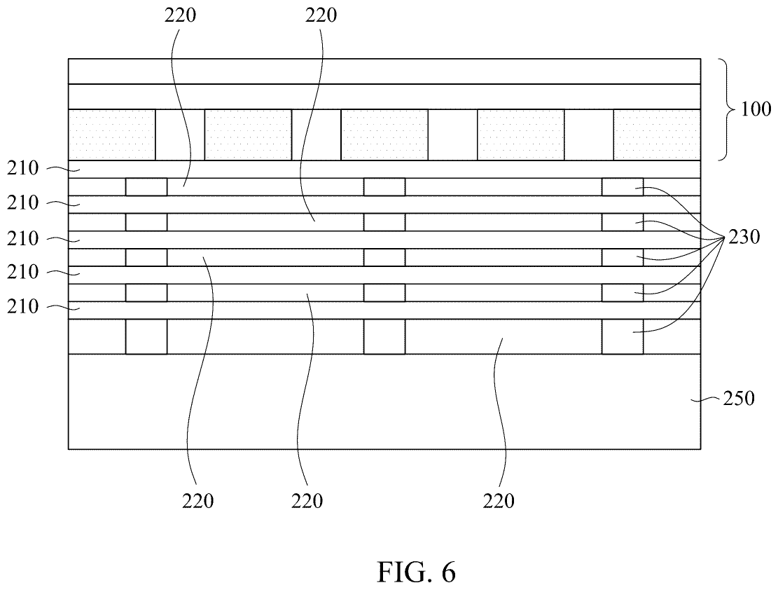

FIG. 6 illustrates a structural diagram of a wire bonding type chip according to some embodiments of the present invention. The top layer of the wire bonding type chip as shown in FIG. 6 is the wire bonding structure 100. There are plural copper metal layers 210 and plural inter-metal dielectric layers 220 alternately disposed under the wire bonding structure 100. There are plural copper metal guide vias 230 provided in each of the inter-metal dielectric layers 220. The bottom layer of the wire bonding type chip is chip 250. It should be noted that the structure of the wire bonding type chip as shown in FIG. 6 is only an example, and the present invention is not limited thereto. The wire bonding structure 100 of the present invention is suitable for any chip packaging device using a wire bonding process.

From the above description, the present invention provides a wire bonding structure that can reduce the longitudinal forward pressure generated during the wire bonding operation to reduce the impact of the longitudinal forward pressure on the electronic component(s) inside the wire bonding type chip, thereby improving the production yield of the wire bonding type chip.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A wire bonding structure suitable for chip packaging devices, comprising:
a wire bonding pad layer;
a metal layer contacting and underneath the wire bonding pad layer; and
a buffer layer contacting and underneath the metal layer;
wherein the buffer layer has a plurality of through holes spaced apart from each other, and the through holes penetrate the buffer layer from top to bottom and correspondingly define a plurality of low dielectric constant material blocks and a plurality of air gaps in a cross-sectional direction of the wire bonding structure, and the low dielectric constant material blocks and the air gaps are laterally interleaved with each other.

2. The wire bonding structure of claim 1, wherein each of the wire bonding pad layer and the metal layer includes aluminum.

3. The wire bonding structure of claim 1, wherein each of the low dielectric constant material blocks includes an undoped silicon glass (USG).

4. The wire bonding structure of claim 1, wherein the low dielectric constant material blocks include oxides or low dielectric constant materials.

5. The wire bonding structure of claim 1, wherein a ratio of a second lateral width of each of the air gaps to a first lateral width of each of the low dielectric constant material blocks is between 0.01 and 0.1.

6. The wire bonding structure of claim 1, wherein a ratio of a first thickness of the buffer layer to a second thickness of the metal layer is less than 8.

7. The wire bonding structure of claim 1, wherein the low dielectric constant material blocks have a same lateral width.

8. The wire bonding structure of claim 1, wherein the air gaps have a same lateral width.

9. A manufacturing method of a wire bonding structure, comprising:
performing a first deposition process to form a low dielectric constant material layer;
utilizing a patterned mask to perform an etching process on the low dielectric constant material layer, thereby forming a plurality of through holes penetrating the low dielectric constant material layer from top to bottom, wherein the through holes define a plurality of low dielectric constant material blocks and a plurality of air gaps in a cross-sectional direction of the wire bonding structure, and the low dielectric constant material blocks and the air gaps are laterally interleaved with each other, wherein the low dielectric constant material blocks and the air gaps form a buffer layer; and
performing a second deposition process to sequentially form a metal layer and a wire bonding pad layer on the buffer layer.

10. The manufacturing method of claim 9, wherein each of the wire bonding pad layer and the metal layer is made of aluminum.

11. The manufacturing method of claim 9, wherein the low dielectric constant material layer is made of an undoped silicon glass (USG).

12. The manufacturing method of claim 9, wherein the low dielectric constant material blocks are made of oxides or low dielectric constant materials.

13. The manufacturing method of claim 9, wherein the patterned mask is designed to adjust a width of each of a plurality of openings of the patterned mask, thereby adjusting a ratio of a second lateral width of each of the air gaps to a first lateral width of each of the low dielectric constant material blocks, wherein the openings of the patterned mask are configured to expose a plurality of portions of the low dielectric constant material layer and the portions respectively correspond to the through holes.

14. The manufacturing method of claim 13, wherein the ratio of the second lateral width of each of the air gaps to the first lateral width of each of the low dielectric constant material blocks is between 0.01 and 0.1.

15. The manufacturing method of claim 9, further comprising:
adjusting process parameters of the first deposition process and the second deposition process to control a ratio of a first thickness of the buffer layer to a second thickness of the metal layer.

16. The manufacturing method of claim 15, wherein the ratio of the first thickness of the buffer layer to the second thickness of the metal layer is less than 8.

17. The manufacturing method of claim 9, wherein the low dielectric constant material blocks have a same lateral width.

18. The manufacturing method of claim 9, wherein the air gaps have a same lateral width.

19. The manufacturing method of claim 9, wherein the first deposition process is a chemical vapor deposition (CVD) process.

20. The manufacturing method of claim 9, wherein the second deposition process is a physical vapor deposition (PVD) process.
